(19) United States
(12) Patent Application Publication
(10) Pub. No.: US 2025/0364786 A1
(43) Pub. Date: Nov. 27, 2025

(54) SOLID STATE LASER DEVICE

(71) Applicant: DELTA ELECTRONICS INT'L (SINGAPORE) PTE LTD., Singapore (SG)

(72) Inventors: Dongdong LI, Singapore (SG); Jack Sheng KEE, Singapore (SG); Teng-Hsiang CHANG, Taoyuan City (TW); En-Hung LIN, Taoyuan City (TW); He ZHANG, Taoyuan City (TW)

(21) Appl. No.: 18/777,553

(22) Filed: Jul. 19, 2024

(30) Foreign Application Priority Data
May 27, 2024 (SG) 10202401502W

(51) Int. Cl. H01S 5/14; G02B 6/12; G02B 6/293; H01S 5/10

(52) U.S. Cl. CPC H01S 5/142; G02B 6/12019; G02B 6/2934; H01S 5/1032; G02B 2006/12061; G02B 2006/12121

(57) ABSTRACT

A solid state laser device includes: a gain circuit unit, and a silicon photonic circuit unit connected with the gain circuit unit. The silicon photonic circuit unit includes: a substrate having an input terminal and an output terminal, the input terminal connected with the gain circuit unit; a light waveguide channel continuously disposed between the input terminal and the output terminal, and having a first section and a second section, the first section connected between the input terminal and the second section; at least two ring resonators disposed on the substrate, two sides of one of the ring resonators coupled with the first section, and two sides of another one of the ring resonators coupled with the second section; and multiple phase shifters respectively disposed on the ring resonators.

### BACKGROUND OF THE DISCLOSURE

### Technical Field

The present disclosure relates to a laser device, particularly relates to a solid state laser device.

### Description of Related Art

In the applications such as autonomous vehicle, unmanned aerial vehicle, or industrial robot, etc., laser is used to perform imaging or sensing as the foundation of analyzing and understanding three dimensional (3D) environment. In a dynamic environment, understanding 3D environment needs to precisely and reliably identify objects, track current positions of the objects, and predict next move of the objects. For example, in the application of autonomous vehicle, the system may need to identify and track many objects in real-time, in which LiDAR is usually used to implement laser imaging, detection, and range-finding.

LiDAR may use, for example, frequency modulated continuous wave (FMCW) laser, and FMCW laser is usually designed as external cavity laser (ECL). ECL structure includes micro ring resonator (MRR) and other optical elements.

In the manufacturing process, the same optical elements may generally have slight size variations or characteristic difference due to uniformity of material and process stability, and the differences is difficult to eliminate by re-processing. Similarly, positions of the elements may be difficult to be precisely aligned during assembly process, and that may cause slight difference to the performances of the same products. With respect to high precision applications, the differences may cause deviations in different levels of precisions or powers between different laser devices, which need to be improved by precise calibrations and cause the manufacturing cost to be greatly increased.

In the applications of detection, range-finding, etc., 3D image with high depth, high precision, and high resolution is desired, and the power of the laser light may influence the capability of detection and range-finding of the photonic integrated circuit applied in the LiDAR. Therefore, how to increase the output power and stability of the laser device is a problem that needs to be solved.

### SUMMARY OF THE DISCLOSURE

The disclosure provides a solid state laser device, which may increase the output power and stability of the laser light.

The disclosure provides a solid state laser device including: a gain circuit unit and a silicon photonic circuit unit connected with the gain circuit unit. The silicon photonic circuit includes: a substrate including an input terminal and an output terminal, the input terminal connected with the gain circuit unit; a light waveguide channel continuously disposed between the input terminal and the output terminal, and including a first section and a second section, the first section connected between the input terminal and the second section; at least two ring resonators disposed on the substrate, two sides of a first one of the ring resonators coupled with the first section, and two sides of a second one of the ring resonators coupled with the second section; and a plurality of phase shifters respectively disposed on the ring resonators.

In some embodiments, the first ring resonators is coupled with the first section at a first point and a second point, a length of the light waveguide channel between the first point and the second point is an integral multiple of a half perimeter of the first ring resonators, and the integral multiple is greater than or equal to two times.

In some embodiments, a cross-sectional area of the first ring resonators is smallest at locations corresponding to the first point and the second point, and the cross-sectional area of the first ring resonators is gradually increased toward directions away from the first point and the second point.

In some embodiments, the first section includes a first arc section and a first linear section, the first linear section is connected with the gain circuit unit, the first arc section is connected with the second section, and two sides of the first ring resonators are coupled with the first arc section.

In some embodiments, the second section includes a second arc section and a second linear section, the second linear section is connected between the first arc section and the second arc section, and two sides of the second ring resonators are coupled with the second arc section.

In some embodiments, the phase shifters are further disposed on the first arc section or the second arc section.

In some embodiments, the phase shifters are respectively disposed on coupling location of the first ring resonators and the first section, and on coupling location of the second ring resonators and the second section.

In some embodiments, the silicon photonic circuit unit further includes: an auxiliary gain chip disposed on the first section or the second section of the light waveguide channel, which includes a light waveguide path disposed therein, and the light waveguide path is a part of the light waveguide channel.

In some embodiments, two sides of the auxiliary gain chip connected with the light waveguide channel are respectively an anti-reflective surface.

In some embodiments, the auxiliary gain chip is embedded in the substrate, and the light waveguide path is aligned with the light waveguide channel on the substrate.

In some embodiments, the gain circuit unit includes: a plurality of gain chips having different lengths, and the light waveguide channel includes a plurality of sub-channels corresponding to the plurality of gain chips.

In some embodiments, a difference of optical path lengths between any two of the plurality of gain chips is an integral multiple of the optical path length of one of the pluralities of gain chips.

In some embodiments, one side of each gain chip connected with the light waveguide channel is an anti-reflective surface, and another side of each gain chip opposite to the anti-reflective surface is a reflective surface.

The disclosure also provides a solid state laser device including: a gain circuit unit and a silicon photonic circuit unit connected with the gain circuit unit. The silicon photonic circuit unit includes: a substrate including an input terminal and an output terminal, the input terminal connected with the gain circuit unit; a light waveguide channel continuously disposed between the input terminal and the output terminal, and including a plurality of arc sections and a plurality of linear sections, and the arc sections and the linear sections arranged alternately; a plurality of ring resonators disposed on the substrate, two sides of each ring resonator coupled with each arc section; and a plurality of phase shifters respectively disposed on each of the plurality of ring resonators.

In some embodiments, each of the plurality of ring resonators is coupled with each of the plurality of arc sections at a first point and a second point, a length of each arc section between the first point and the second point is an integral multiple of a half perimeter of respective ring resonator, and the integral multiple is greater than or equal to two times.

In some embodiments, a cross-sectional area of each of the plurality of ring resonators is smallest at locations corresponding to the first point and the second point, and the cross-sectional area of each of the plurality of ring resonators is gradually increased toward directions away from the first point and the second point.

In some embodiments, the silicon photonic circuit unit further includes: an auxiliary gain chip disposed on one of the plurality of the arc sections, which includes a light waveguide path disposed therein, and the light waveguide path is a part of the light waveguide channel.

In some embodiments, two sides of the auxiliary gain chip connected with the light waveguide channel are respectively an anti-reflective surface.

In some embodiments, the phase shifters are respectively disposed on coupling locations of at least one of the plurality of ring resonators and one of the plurality of arc sections.

In some embodiments, the phase shifters are further disposed on at least one of the plurality of arc sections.

In summary, the light waveguide channel of the solid state laser device in the disclosure is continuously disposed between the input terminal and the output terminal of the substrate of the silicon photonic circuit unit. In other words, the light waveguide channel between the input terminal and the output terminal is substantially a closed path. Thus, if the coupling parameter between two sides of the ring resonator and the light waveguide channel is unstable because of the gaps therebetween being inconsistent, a portion of the light from the light waveguide channel may not be coupled to the ring resonator, and the uncoupled light may still pass along the closed light waveguide channel to form constructive interference so as to be re-coupled to the ring resonator. As a result, the solid state laser device of the disclosure may prevent light loss and further increase the output power and stability of the laser light.

Further, the solid state laser device of the disclosure may further have the phase shifters disposed on the arc sections of the light waveguide channel to adjust the constructive interference at the locations so as to compensate the processing deviation and the differences of light wavelengths, etc., and further increase the output power of the laser light. Moreover, the solid state laser device of the disclosure may also have the phase shifter disposed on the coupling locations of the ring resonators and the light waveguide channel to adjust the coupling parameters of the ring resonators and reflection indices of the light waveguide channel, etc., and further make the output power of the laser light become more stable in addition to increasing the output power of the laser light. The solid state laser device of the disclosure may have the compensating gain chip (the auxiliary gain chip) disposed on the light waveguide channel to further amplify the power of the laser light in the light waveguide channel.

### BRIEF DESCRIPTION OF THE DRAWINGS

FIG. 1 is a schematic diagram of the first embodiment of the solid state laser device in the disclosure.

FIG. 2 is a schematic diagram of the solid state laser device in the related art.

FIG. 3 is a schematic diagram of the second embodiment of the solid state laser device in the disclosure.

FIG. 4 is a schematic diagram of the third embodiment of the solid state laser device in the disclosure.

FIG. 5 is a schematic diagram of the variant embodiment of the auxiliary gain chip in the disclosure.

FIG. 6 is a schematic diagram of the variant embodiment of the ring resonator in the disclosure.

FIG. 7 is a schematic diagram of the fourth embodiment of the solid state laser device in the disclosure.

FIG. 8 is a schematic diagram of the fifth embodiment of the solid state laser device in the disclosure.

FIG. 9 is a flowchart of the manufacturing method of the solid state laser device in the disclosure.

FIG. 10 is a flowchart of the optical transmitting method of the solid state laser device in the disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

As used in the present disclosure, terms such as “first”, “second”, “third”, “fourth”, and “fifth” are employed to describe various elements, components, regions, layers, and/or parts. These terms should not be construed as limitations on the mentioned elements, components, regions, layers, and/or parts. Instead, they are used merely for distinguishing one element, component, region, layer, or part from another. Unless explicitly indicated in the context, the usage of terms such as “first”, “second”, “third”, “fourth”, and “fifth” does not imply any specific sequence or order.

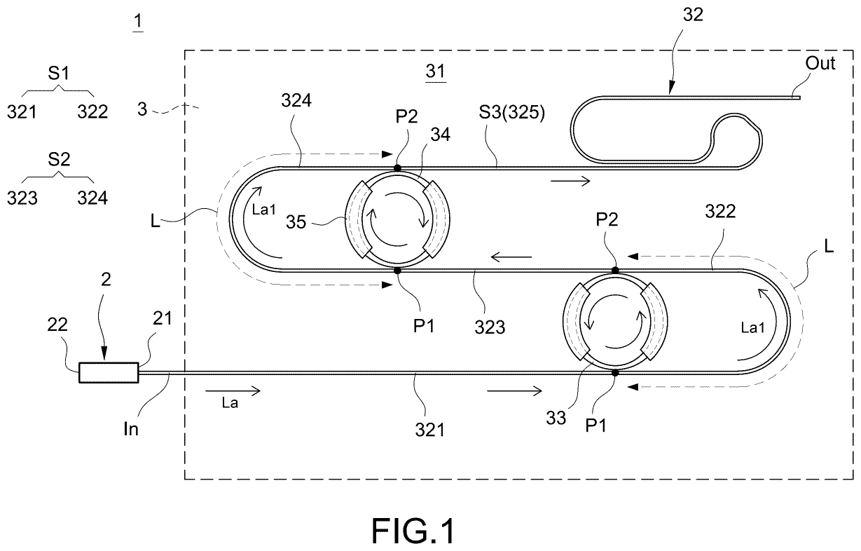

FIG. 1 is a schematic diagram of the first embodiment of the solid state laser device in the disclosure. As shown in FIG. 1, the solid state laser device 1 of the embodiment may be, for example, an external cavity laser (ECL), which may include a gain circuit unit 2 and a silicon photonic circuit unit 3. The silicon photonic circuit unit 3 is connected with the gain circuit unit 2.

In some embodiments, the gain circuit unit 2, for example, may include one or a plurality of gain chips. The gain chip may be a reflective semiconductor optical amplifier (RSOA). The gain chip has a portion of the laser cavity for emitting the laser light La. In some embodiments, one side of the gain circuit unit 2 (for example, the gain chip therein) connected with the light waveguide channel 32 of the silicon photonic circuit unit 3 is an anti-reflective surface 21, and the other side of the gain circuit unit 2 opposite to the anti-reflective surface 21 is a reflective surface 22.

The silicon photonic circuit unit 3 includes a substrate 31, a light waveguide channel 32, at least two ring resonators 33, 34, and a plurality of phase shifters 35. The substrate 31 has an input terminal In and an output terminal Out. The input terminal In is connected with the gain circuit unit 2, and the output terminal Out is used for outputting the laser light La. It should be noted that a plurality of different film layers may be disposed on the substrate 31, here is not intended to be limiting.

The light waveguide channel 32 may be formed by, for example, photolithography process or other suitable patterning process. The light waveguide channel 32 is used to confine the laser light La therein by the differences of refractive indices. The light waveguide channel 32 is continuously disposed between the input terminal In and the output terminal Out. That is, the light waveguide channel 32 substantially forms a closed path between the input terminal In and the output terminal Out. In some embodiments, the light waveguide channel 32 has a first section S1 and a second section S2. The first section S1 is connected between the input terminal In and the second section S2.

The ring resonators 33, 34 are, for example, the micro ring resonator (MRR) structure. The ring resonators 33, 34 may be light waveguide mediums having the same characteristics as the light waveguide channel 32, and made by the same process as the light waveguide channel 32. The ring resonators 33, 34 are structured in curved ring shape to make the laser light La resonate to adjust the frequency. The ring resonators 33, 34 are disposed on the substrate 31. Two sides of the ring resonator 33 are coupled in the first section S1 at the first point P1 and the second point P2. Two sides of the ring resonator 34 are coupled in the second section S2 at the first point P1 and the second point P2.

In the embodiment, as an example, the light waveguide channel 32 includes a plurality of linear sections 321, 323, 325 and a plurality of arc sections 322, 324, here is not intended to be limiting. For example, the first section S1 includes the linear section 321 and the arc section 322, and the second section S2 includes the linear section 323 and the arc section 324, here is not intended to be limiting. It should be noted that the arc sections 322, 324 are located between the first point P1 and the second point P2, and the arc sections 322, 324 may be shaped with perfect circle arc, ellipse arc, oval arc, or other gradient arc.

The linear sections 321, 323, 325 and the arc sections 322, 324 are arranged alternately. That is the light waveguide channel 32 is formed with a sequence of linear section, arc section, linear section, and arc section, etc. For example, the linear section 321 of the first section S1 is connected between the gain circuit unit 2 and the first point P1 at one side of the ring resonator 33, the arc section 322 of the first section S1 is connected between the first point P1 and the second point P2 at two sides of the ring resonator 33, the linear section 323 of the second section S2 is connected between the second point P2 at another side of the ring resonator 33 and the first point P1 at one side of the ring resonator 34, and the arc section 324 of the second section S2 is connected between the first point P1 and the second point P2 at two sides of the ring resonator 34. It is worth mentioning that, in some embodiments, the light waveguide channel 32 may further have the third section S3. The third section S3 is connected between the arc section 324 of the second section S2 and the output terminal Out. Definitely, if more ring resonators are disposed, the third section may be formed as the first section or the second section, which has the linear section and the arc section, to be coupled with the ring resonator. Further, the light waveguide channel 32 may also have more sections as the first section or the second section with respect to more ring resonators

It is worth mentioning that the ring resonator 33 is coupled with the arc section 322 of the first section S1 at the first point P1 and the second point P2, and a length L of the arc section 322 of the light waveguide channel 32 between the first point P1 and the second point P2 is desirably an integral multiple of a half perimeter of the ring resonator 33, and the integral multiple is greater than or equal to two times, here is not intended to be limiting. For example, if the ring resonator 33 is a perfect circle, the length L between the first point P1 and the second point P2 of the light waveguide channel 32 is equal to NÆR. That is, L=NÆR, which N is a positive integer greater than or equal to 2, and R is radius of the ring resonator 33. Of course, for the ring resonator 34, the length of the arc section 324 of the light waveguide channel 32 at the second section S2 is desirably set with the same requirement. Moreover, the ring resonators 33, 34 are not limited to perfect circle, the ring resonators 33, 34 may be shaped in ellipse, oval, or the other shape structured by arcs with curvature.

It is worth mentioning that, in the embodiment, two ring resonators 33, 34 are used as an example, here is not intended to be limiting. The silicon photonic circuit unit may have two or more than two ring resonators according to different designs or requirements. The light waveguide channel may correspondingly have two or more than two arc sections and corresponding linear sections for the ring resonators to be disposed. However, the light waveguide channel should be continuously disposed (formed as a closed path in between) on the substrate as a requirement.

The phase shifter 35, for example, may include a heater. The phase shifter 35 is disposed to adjust the phase of the light waveguide (such as the ring resonators 33, 34) to assist the frequency modulation of the laser light. The phase shifters 35 are disposed on the upper side or periphery of the ring resonators 33, 34 respectively. In the embodiment, the phase shifters 35 are respectively disposed on left sides and right sides of the ring resonators 33, 34. In some other embodiments, the phase shifters 35 may also be disposed around the first points P1 and the second points P2 where the ring resonators 33, 34 are coupled with the light waveguide channel 32, here is not intended to be limiting.

Therefore, the laser light La may enter the light waveguide channel 32 of the silicon photonic circuit unit 3 from the gain circuit unit 2. When the laser light La pass through the coupling locations (for example, the first point P1) of the light waveguide channel 32 and the ring resonator 33, most of the laser light La is coupled to the ring resonator 33, but a portion of the laser light La1 may not be coupled to the ring resonator 33 and emit to the arc section 322. The first section S1 and the second section S2 of the light waveguide channel 32 may form a closed path through the connection of the arc section 322, thus the laser light La1 may still pass along the closed light waveguide channel 32 to another coupling location (for example, the second point P2) of the light waveguide channel 32 and the other side of the ring resonator 33 so as to be re-coupled to the ring resonator 33. As a result, the loss of the laser light La1 may be prevented. Similarly, with respect to the ring resonator 34, the loss of the laser light may be prevented again.

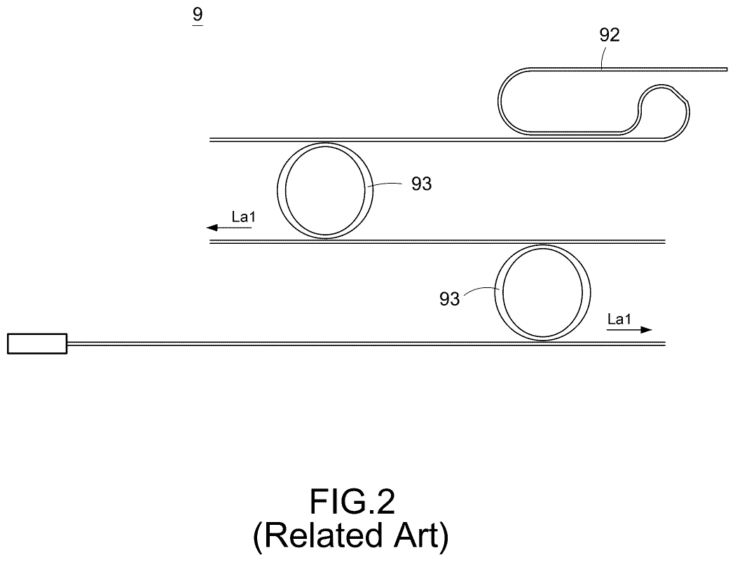

FIG. 2 is a schematic diagram of the solid state laser device in the related art. As shown in FIG. 2, the light waveguide channel 92 of the solid state laser device 9 is an open path. Therefore, at the coupling location of the light waveguide channel 92 and the ring resonator 93, if a portion of the laser light La1 is not coupled to the ring resonator 93, the laser light La1 may be lost at the open end of the light waveguide channel 92 and further cause the output power of the laser light to be decreased.

Referring back to FIG. 1, on the other hand, the light waveguide channel 32 of the solid state laser device 1 in the embodiment is continuously disposed between the input terminal In and the output terminal Out of the substrate 31 of the silicon photonic circuit unit 3. In other words, the light waveguide channel 32 between the input terminal In and the output terminal Out is substantially a closed path. Thus, if the coupling parameter between two sides of the ring resonators 33, 34 and the light waveguide channel 32 is unstable due to the gaps therebetween are inconsistent, leading to a portion of the laser light La1 from the light waveguide channel 32 not coupled to the ring resonators 33, 34. In this condition, the laser light La1 may still pass along the closed light waveguide channel 32 to form constructive interference and thus be re-coupled to the ring resonators 33, 34. As a result, the solid state laser device 1 of the embodiment may prevent the loss of the laser light La1 and further increase the output power and stability of the laser light La.

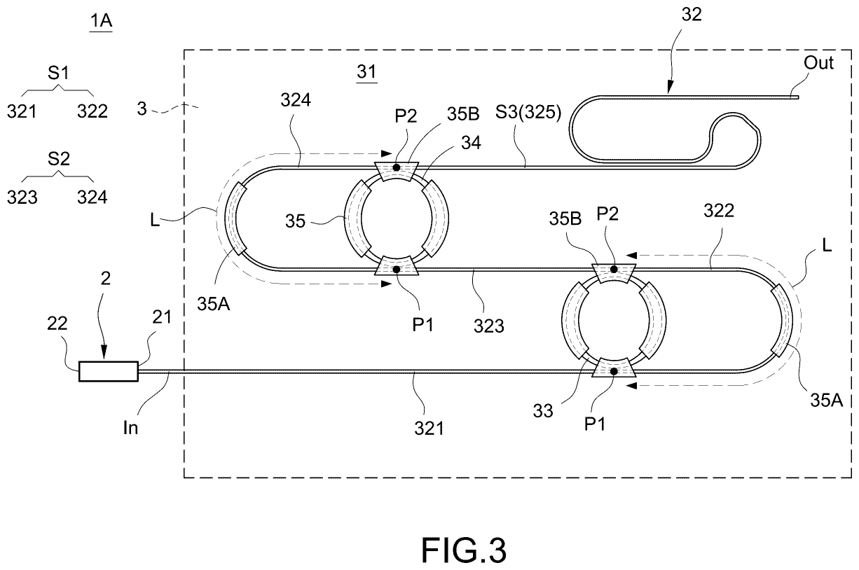

FIG. 3 is a schematic diagram of the second embodiment of the solid state laser device in the disclosure. As shown in FIG. 1 and FIG. 3, the differences between the solid state laser device 1A of the second embodiment and the solid state laser device 1 of the first embodiment are that the phase shifters 35A are further disposed on the arc section 322 of the first section S1 and the arc section 324 of the second section S2, and the phase shifters 35B are further disposed on the coupling locations (the first point P1 and the second point P2) of the ring resonator 33 and the first section S1 of the light waveguide channel 32, and disposed on the coupling locations (the first point P1 and the second point P2) of the ring resonator 34 and the second section S2 of the light waveguide channel 32.

The reflection indices of the arc sections 322, 324 and the constructive interference of the laser light may be adjusted by disposing the phase shifters 35A on the arc section 322 of the first section S1 and the arc section 324 of the second section S2. Thereby the processing deviation and the differences of light wavelengths, etc., may be compensated to further increase the output power of the laser light.

On the other hand, the coupling parameter of the ring resonators 33, 34 and reflection index of the light waveguide channel 32, etc., may be adjusted by disposing the phase shifters 35B on the coupling locations of the ring resonators 33, 34 and the light waveguide channel 32. And in addition to increasing the output power of the laser light, the output power of the laser light may be further stabilized.

It should be noted that, in the embodiment, the phase shifters 35A and the phase shifters 35B are fully disposed as an example. But in the practical application, the phase shifters 35A or the phase shifters 35B may be solely disposed, or the phase shifters 35A may be solely disposed on the arc section 322 or the arc section 324, or the phase shifters 35B may be solely disposed on the coupling location of the ring resonator 33 and the light waveguide channel 32, or the phase shifters 35B may be solely disposed on the coupling location of the ring resonator 34 and the light waveguide channel 32, here is not intended to be limiting.

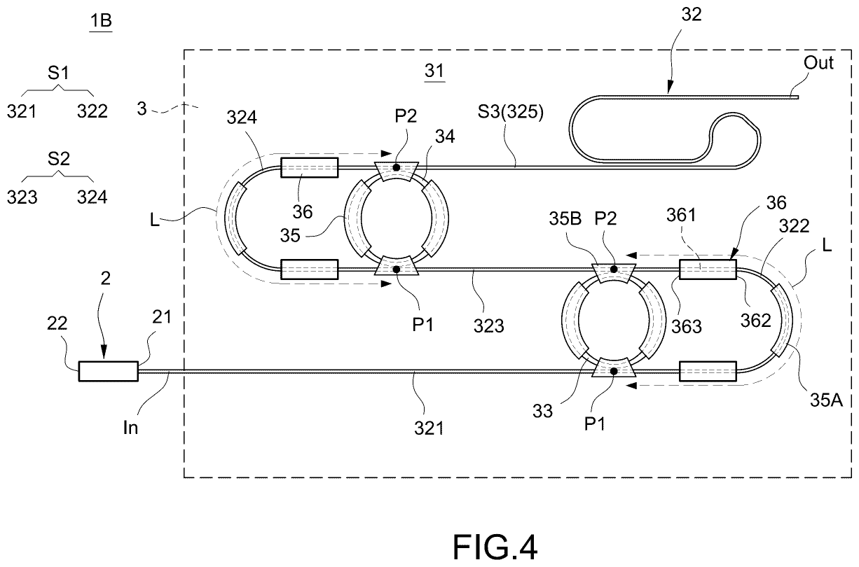

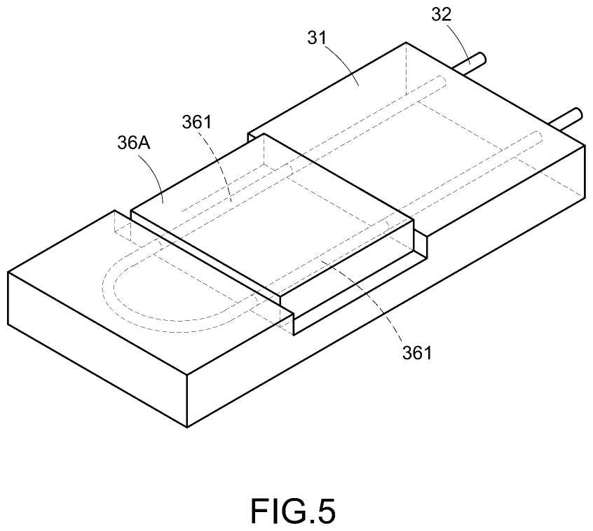

FIG. 4 is a schematic diagram of the third embodiment of the solid state laser device in the disclosure. As shown in FIG. 3 and FIG. 4, the differences between the solid state laser device 1B of the third embodiment and the solid state laser device 1A of the second embodiment are that the silicon photonic circuit unit 3 further includes auxiliary gain chip 36. The auxiliary gain chip 36 is disposed on the first section S1 and the second section S2 of the light waveguide channel 32. The auxiliary gain chip 36 has light waveguide path 361 disposed therein, and the light waveguide path 361 constitute part of the light waveguide channel 32. That is, the auxiliary gain chip 36 is embedded in the substrate 31, and the light waveguide path 361 is aligned with the light waveguide channel 32 on the substrate 31 (for example, as shown in FIG. 5 below). In some embodiments, two sides of the auxiliary gain chip 36 connected with the light waveguide channel 32 are both anti-reflective surfaces 362, 363 to prevent the reflection of the laser light causing the loss of light energy.

Specifically, the auxiliary gain chip 36 may be disposed on the arc section 322 of the first section S1 and the arc section 324 of the second section S2 of the light waveguide channel 32. That is, the auxiliary gain chip 36 may be, for example, disposed at two ends of the arc section 322 close to the first point P1 and the second point P2, and two ends of the arc section 324 close to the first point P1 and the second point P2. As a result, when a portion of the laser light is not coupled to the ring resonators 33, 34 and emits to the arc sections 322, 324, the power of the laser light in the arc sections 322, 324 of the light waveguide channel 32 may be further amplified by the auxiliary gain chip 36.

It is worth mentioning that the auxiliary gain chip 36 may be disposed only on the arc section 322 of the first section S1 or the arc section 324 of the second section S2 of the light waveguide channel 32, or the auxiliary gain chip 36 may be disposed on either ends of the arc sections 322, 324.

It should be noted that the auxiliary gain chip 36 may be applied to the solid state laser device 1 (as shown in FIG. 1) in the first embodiment, the description is omitted for brevity. FIG. 5 is a schematic diagram of the variant embodiment of the auxiliary gain chip in the disclosure. As shown in FIG. 5, the auxiliary gain chip 36A may have two light waveguide paths 361. In other words, the auxiliary gain chip 36A is embedded in the substrate 31, and the light waveguide paths 361 are respectively aligned with different sections of the light waveguide channel 32 on the substrate 31. For example, the light waveguide paths 361 of the auxiliary gain chip 36A may be disposed corresponding to the arc section of the first section and/or the arc section of the second section. As a result, the amount of the auxiliary gain chip 36A may be decreased to simplify the manufacturing process and reduce the cost.

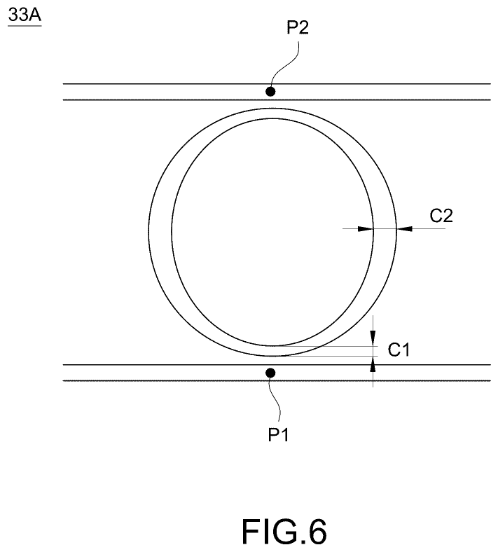

FIG. 6 is a schematic diagram of the variant embodiment of the ring resonator in the disclosure. As shown in FIG. 6, a cross-sectional area C1 of the ring resonator 33A is smallest at locations corresponding to the first point P1 and the second point P2, and the cross-sectional area is gradually increased toward directions away from the first point P1 and the second point P2. In other words, the cross-sectional area C2 of the ring resonator 33A, for example, at the middle locations is biggest, or the cross-sectional area C2 of the ring resonator 33A at the location farthest from the first point P1 and the second point P2 is the biggest.

Therefore, the cross-sectional area Cl of the ring resonator 33A is, for example, single mode at the location corresponding to the first point P1 and the second point P2, and the cross-sectional area C2 at the middle location may become multi-mode. As a result, the scattering loss of the laser light due to defects on the inner surface of the ring resonator 33A may be prevented since the ring resonator 33A operating in multi-mode at the middle location, and the power loss of the laser light transmitting in the ring resonator 33A may be further decreased. It should be noted that the ring resonator 33A may be applied to any embodiment of the solid state laser device in the disclosure.

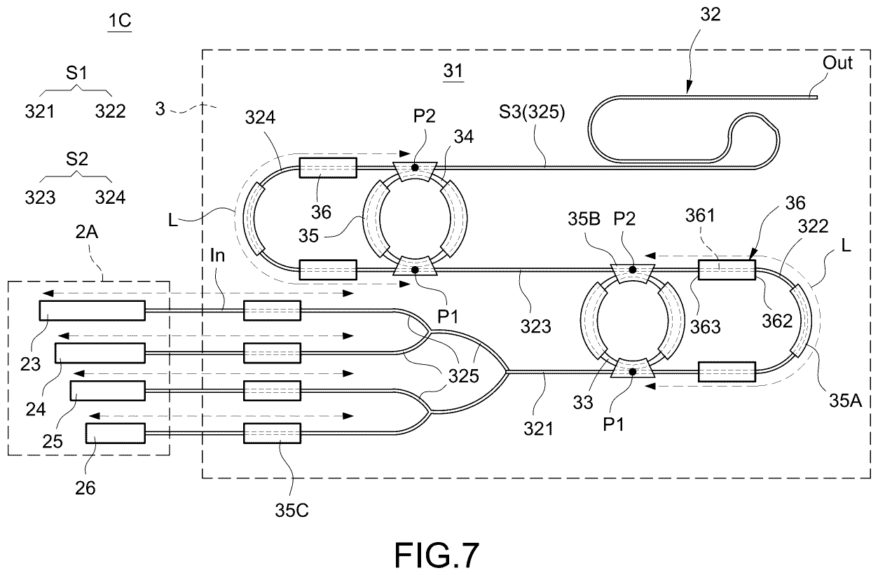

FIG. 7 is a schematic diagram of the fourth embodiment of the solid state laser device in the disclosure. As shown in FIG. 4 and FIG. 7, the difference of the solid state laser device 1C of the fourth embodiment to the solid state laser device 1B of the third embodiment is that the gain circuit unit 2A includes a plurality of gain chips 23, 24, 25, 26. The gain chips 23, 24, 25, 26 have different lengths, and the light waveguide channel 32 has a plurality of sub-channels 325 corresponding to the gain chips 23, 24, 25, 26. Further, the lengths of the portions of the sub-channels 325 connected to the gain chips 23, 24, 25, 26 are the same. It should be noted that, in the embodiment, the lengths of the gain chips 23, 24, 25, 26 are gradually decreased from top to bottom as an example, here is not intended to be limiting. The main consideration is that the optical path differences between the gain chips 23, 24, 25, 26 may generate constructive interference. In some embodiments, the differences of optical path lengths between the gain chips 23, 24, 25, 26 are in integral multiple. For example, the difference of optical path lengths between any two of the gain chips 23, 24, 25, 26 is an integral multiple of the optical path length of one of the gain chips 23, 24, 25, 26.

It is worth mentioning that the phase shifter 35C may be disposed on the sub-channels 325 to adjust the reflection index of the sub-channels 325 and the constructive interference of the laser light, etc., here is not intended to be limiting.

Therefore, with the gain chips 23, 24, 25, 26 having different lengths, different optical path differences may be provided to generate the constructive interference. Further, the gain and the output power of the laser light may be further increased by parallelly arranging a plurality of gain chips 23, 24, 25, 26.

It should be noted that the gain chips 23, 24, 25, 26 and the sub-channels 325 in the embodiment may be applied to the solid state laser device 1 (as shown in FIG. 1) in the first embodiment and the solid state laser device 1A (as shown in FIG. 3) in the second embodiment, the description is omitted for brevity.

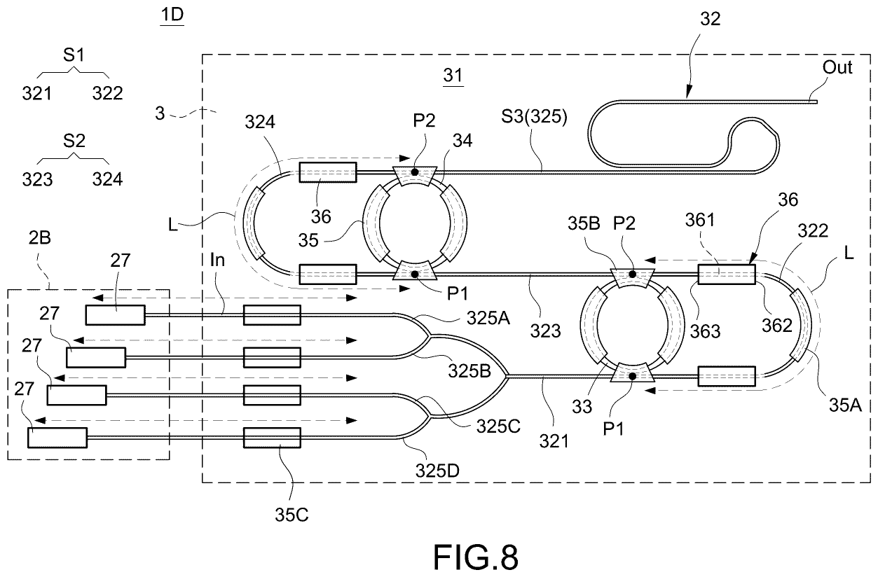

FIG. 8 is a schematic diagram of the fifth embodiment of the solid state laser device in the disclosure. As shown in FIG. 7 and FIG. 8, the differences between the solid state laser device 1D of the fifth embodiment and the solid state laser device 1C of the fourth embodiment are that the gain chips 27 in the gain circuit unit 2B all have the same length, and the lengths of the portions of the sub-channels 325A, 325B, 325C, 325D connected to the gain chips 27 are different. It should be noted that, in the embodiment, the lengths of the sub-channels 325A, 325B, 325C, 325D are gradually decreased from top to bottom as an example, here is not intended to be limiting. The main consideration is that the optical path differences between the gain chips 276 may generate constructive interference. In some embodiments, the optical path differences between the gain chips 27 are in integral multiple. For example, the optical path difference between any two gain chips 27 is an integral multiple of the optical path length of one of the gain chips or another optical path difference.

Specifically, if the length of the gain chip is relatively longer, the output power is relatively higher, but the efficiency is relatively lower. On the other hand, if the length of the gain chip is relatively shorter, the output power is relatively lower, but the efficiency is relatively higher. Therefore, different designs may be used depending on different considerations.

It should be noted that the gain chips 27 and the sub-channels 325A, 325B, 325C, 325D in the embodiment may be applied to the solid state laser device 1 (as shown in FIG. 1) in the first embodiment and the solid state laser device 1A (as shown in FIG. 3) in the second embodiment, the description is omitted for brevity.

It is worth mentioning that the embodiments in the FIG. 7 and FIG. 8 may be collectively used. That is, some of the gain chips are of the same length, and some of the gain chips are of different lengths with the sub-channel in different lengths correspondingly.

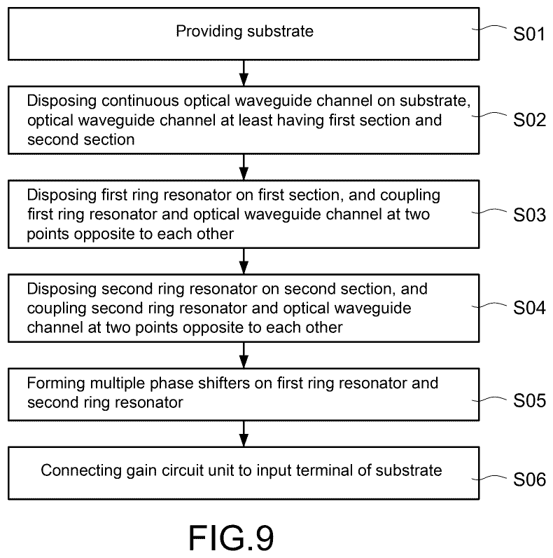

FIG. 9 is a flowchart of the manufacturing method of the solid state laser device in the disclosure. As shown in FIG. 9, the manufacturing method of the solid state laser device in the disclosure includes the step S01 to the step S05. The step S01 is providing the substrate. The step S02 is disposing the continuous optical waveguide channel on the substrate, and the optical waveguide channel at least has the first section and the second section. The step S03 is disposing the first ring resonator on the first section, and coupling the first ring resonator and the optical waveguide channel at two points opposite to each other. The step S04 is disposing the second ring resonator on the second section, and coupling the second ring resonator and the optical waveguide channel at two points opposite to each other. The step S05 is forming a plurality of phase shifters on the first ring resonator and the second ring resonator. The step S06 is connecting the gain circuit unit to the input terminal of the substrate.

In some embodiments, the step S02 may further includes disposing a plurality of auxiliary gain chips on the substrate to be located on the light waveguide channel. The auxiliary gain chip has a light waveguide path disposed therein, and the light waveguide path is a part of the light waveguide channel.

In some embodiments, the step S05 may further includes disposing the phase shifters on the coupling location of the first ring resonator and the light waveguide channel, and the coupling location of the second ring resonator and the light waveguide channel.

In some embodiments, the step S06 may further includes connecting a plurality of gain chips on the input terminal of the substrate.

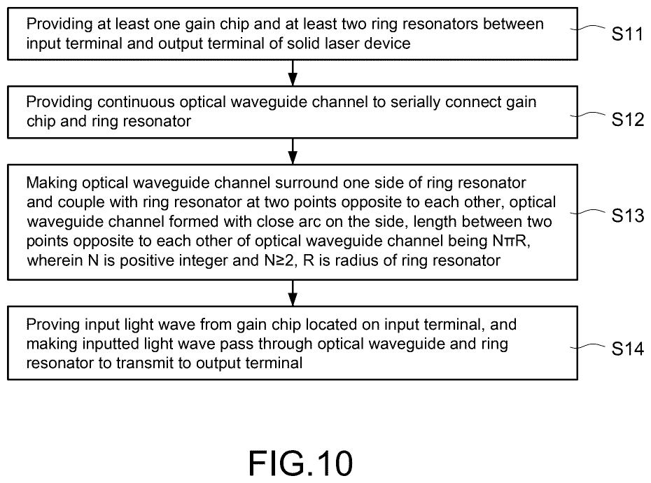

FIG. 10 is a flowchart of the optical transmitting method of the solid state laser device in the disclosure. As shown in FIG. 10, the optical transmitting method of the solid state laser device in the disclosure includes the step S11 to the step S14. The step S11 is providing at least one gain chip and at least two ring resonators between the input terminal and the output terminal of the solid laser device. The step S12 is providing the continuous optical waveguide channel to serially connect the gain chip and the ring resonator. The step S13 is making the optical waveguide channel surround one side of the ring resonator and couple with the ring resonator at two points opposite to each other, the optical waveguide channel forms a closed arc on the side, and the length between two points opposite to each other of the optical waveguide channel is NπR, wherein N is a positive integer and N>2, R is radius of the ring resonator. The step S14 is proving the input light wave from the gain chip located on the input terminal, and making the inputted light wave pass through the optical waveguide and the ring resonator to transmit to the output terminal.

In some embodiments, the step S12 further includes providing the phase shifters at the coupling locations of the ring resonator and the light waveguide channel to make the coupling parameters of two coupling points of the same ring resonator be the same.

In some embodiments, the step S12 further includes providing an auxiliary gain chip or the phase shifters to the light waveguide channel to enhance the light intensity of the section in the light waveguide channel or adjust the coupling parameter of the section.

In some embodiments, the step S14 further includes using a plurality of gain chips on the input terminal to generate a plurality of light beams to form the input light. The light beams have the optical path differences in an integral multiple therebetween.

In summary, the light waveguide channel of the solid state laser device in the disclosure is continuously disposed between the input terminal and the output terminal of the substrate of the silicon photonic circuit unit. In other words, the light waveguide channel between the input terminal and the output terminal is substantially a closed path therebetween. Thus, if the coupling parameter between two sides of the ring resonator and the light waveguide channel is unstable due to the gaps therebetween being inconsistent, a portion of the light from the light waveguide channel may not be coupled to the ring resonator, still the uncoupled light may still pass along the closed light waveguide channel to form constructive interference and thus be re-coupled to the ring resonator. As a result, the solid state laser device of the disclosure may prevent light loss and further increase the output power and stability of the laser light.

Further, phase shifters of the solid state laser device of the disclosure may further be disposed on the arc sections of the light waveguide channel to adjust the constructive interference at these locations so as to compensate the process deviation and the difference of light wavelength, etc., and further increase the output power of the laser light. Moreover, phase shifters of the solid state laser device of the disclosure may also be disposed on the coupling locations of the ring resonators and the light waveguide channel so as to adjust the coupling parameter of the ring resonators and reflection index of the light waveguide channel, etc., and further make the output power of the laser light be more stable in addition to increasing the output power of the laser light. The compensating gain chip (the auxiliary gain chip) of the solid state laser device of the disclosure may be disposed on the light waveguide channel to further amplify the power of the laser light in the light waveguide channel.

While this disclosure has been described by means of specific embodiments, numerous modifications and variations may be made thereto by those skilled in the art without departing from the scope and spirit of this disclosure set forth in the claims.

What is claimed is:

1. A solid state laser device, comprising:
a gain circuit unit; and
a silicon photonic circuit unit, connected with the gain circuit unit, and comprising:
a substrate, comprising an input terminal and an output terminal, the input terminal connected with the gain circuit unit;
a light waveguide channel, continuously disposed between the input terminal and the output terminal, comprising a first section and a second section, the first section connected between the input terminal and the second section;
at least two ring resonators, disposed on the substrate, two sides of one of the ring resonators coupled with the first section, and two sides of another one of the ring resonators coupled with the second section; and
a plurality of phase shifters, respectively disposed on the ring resonators.

2. The solid state laser device according to claim 1, wherein the one of the ring resonators is coupled with the first section at a first point and a second point, a length of the light waveguide channel between the first point and the second point is an integral multiple of a half perimeter of the one of the ring resonators, and the integral multiple is greater than or equal to two times.

3. The solid state laser device according to claim 2, wherein a cross-sectional area of the one of the ring resonators is smallest at locations corresponding to the first point and the second point, and the cross-sectional area of the one of the ring resonators is gradually increased toward directions away from the first point or the second point.

4. The solid state laser device according to claim 1, wherein the first section comprises a first arc section and a first linear section, the first linear section is connected with the gain circuit unit, the first arc section is connected with the second section, and two sides of the one of the ring resonators are coupled with the first arc section.

5. The solid state laser device according to claim 4, wherein the second section comprises a second arc section and a second linear section, the second linear section is connected between the first arc section and the second arc section, and two sides of the another one of the ring resonators are coupled with the second arc section.

6. The solid state laser device according to claim 5, wherein the phase shifters are further disposed on the first arc section and/or the second arc section.

7. The solid state laser device according to claim 1, wherein the phase shifters are respectively disposed on coupling location of the one of the ring resonators and the first section, and/or on coupling location of the another one of the ring resonators and the second section.

8. The solid state laser device according to claim 1, wherein the silicon photonic circuit unit further comprises:
an auxiliary gain chip, disposed on the first section and/or the second section of the light waveguide channel, comprising a light waveguide path disposed therein, and the light waveguide path is a part of the light waveguide channel.

9. The solid state laser device according to claim 8, wherein two sides of the auxiliary gain chip connected with the light waveguide channel are respectively an anti-reflective surface.

10. The solid state laser device according to claim 8, wherein the auxiliary gain chip is embedded in the substrate, and the light waveguide path is aligned with the light waveguide channel on the substrate.

11. The solid state laser device according to claim 1, wherein the gain circuit unit comprises:
a plurality of gain chips, having different lengths respectively,
wherein the light waveguide channel comprises a plurality of sub-channels corresponding to the plurality of gain chips respectively.

12. The solid state laser device according to claim 11, wherein a difference of optical path lengths between any two of the plurality of gain chips is an integral multiple of the optical path length of one of the plurality of gain chips.

13. The solid state laser device according to claim 11, wherein one side of each of the plurality of gain chips connected with the light waveguide channel is an anti-reflective surface, and another side of each of the plurality of gain chips opposite to the anti-reflective surface is a reflective surface.

14. A solid state laser device, comprising:
a gain circuit unit; and
a silicon photonic circuit unit, connected with the gain circuit unit, and comprising:
a substrate, comprising an input terminal and an output terminal, the input terminal connected with the gain circuit unit;
a light waveguide channel, continuously disposed between the input terminal and the output terminal, comprising a plurality of arc sections and a plurality of linear sections, and the arc sections and the linear sections arranged alternately;
a plurality of ring resonators, disposed on the substrate, and two sides of each of the plurality of ring resonators coupled with each of the plurality of arc sections; and
a plurality of phase shifters, respectively disposed on each of the plurality of ring resonators.

15. The solid state laser device according to claim 14, wherein each of the plurality of ring resonators is coupled with each of the plurality of arc sections respectively at a first point and a second point, a length of each of the plurality of arc sections between the first point and the second point is an integral multiple of a half perimeter of the respective ring resonator, and the integral multiple is greater than or equal to two times.

16. The solid state laser device according to claim 15, wherein a cross-sectional area of each of the plurality of ring resonators is smallest at locations corresponding to the first point and the second point, and the cross-sectional area of each of the plurality of ring resonator sis gradually increased toward directions away from the first point and the second point.

17. The solid state laser device according to claim 14, wherein the silicon photonic circuit unit further comprises:
an auxiliary gain chip, disposed on one of the of the plurality of arc sections, comprising a light waveguide path disposed therein, and the light waveguide path is a part of the light waveguide channel.

18. The solid state laser device according to claim 17, wherein two sides of the auxiliary gain chip connected with the light waveguide channel are respectively an anti-reflective surface.

19. The solid state laser device according to claim 14, wherein the phase shifters are respectively disposed on coupling locations of at least one of the of the plurality of ring resonators and one of the of the plurality of arc sections.

20. The solid state laser device according to claim 14, wherein the phase shifters are further disposed on at least one of the of the plurality of arc sections.
